(19) United States
(12) Patent Application Publication
(10) Pub. No.: US 2009/0170335 A1
(43) Pub. Date: Jul. 2, 2009

(54) PLASMA ETCHING METHOD, PLASMA ETCHING APPARATUS, CONTROL PROGRAM AND COMPUTER-READABLE STORAGE MEDIUM

(75) Inventors: Satoshi TANAKA, Nirasaki-shi (JP); Yoshinobu Ooya, Nirasaki-shi (JP); Fumio Yamazaki, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/341,205

(22) Filed: Dec. 22, 2008

Related U.S. Application Data
(60) Provisional application No. 61/033,295, filed on Mar. 3, 2008.

(30) Foreign Application Priority Data
Dec. 27, 2007 (JP) 2007-335681

(51) Int. Cl. H01L 21/3065

(52) U.S. Cl. 438/723; 156/345.29; 257/E21.218

(57) ABSTRACT

A plasma etching method for performing an etching process for forming on an insulating film formed on a substrate a hole shape having a ratio of depth to opening width of more than 20. The hole shape is formed on the insulating film by converting processing gas containing at least C₄F₆ gas and C₆F₆ gas into a plasma. A flow rate ratio of the C₄F₆ gas to the C₆F₆ gas (C₄F₆ gas flow rate/C₆F₆ gas flow rate) ranges from 2 to 11.

### FIELD OF THE INVENTION

The present invention relates to a plasma etching method for etching an insulating layer formed on a substrate, a plasma etching apparatus, a control program and a computer-readable storage medium.

### BACKGROUND OF THE INVENTION

In a conventional semiconductor device manufacturing process, a plasma etching process is performed via a mask layer, and a through hole for forming a contact or a hole shape for forming a capacitor is formed on an insulating layer such as a silicon oxide layer or the like.

Further, it is known that fluorocarbon gas is used to plasma-etch the silicon oxide layer. Furthermore, it is known that C₄F₈ gas, C₄F₆ gas, C₆F₆ gas or the like is used as the fluorocarbon gas (see, e.g., Patent Document 1).

When the insulating layer is etched, it is required to form a through hole or a hole shape of a high ratio of depth to opening width (high aspect ratio). When the through hole or the hole shape of a high aspect ratio is formed, a high selectivity to the mask layer is required. As for an additive gas for realizing a high selectivity, C₄F₈ gas and C₄F₆ gas are known. Especially, C₄F₆ gas is effective to improve the selectivity. Accordingly, as for processing gas for forming a through hole or a hole shape which has a high aspect ratio, there is used, e.g., a gaseous mixture of Ar gas, O₂ gas and C₄F₆ gas.

[Patent Document 1] Japanese Patent Laid-open Publication No. 2001-110790

In the etching for forming a through hole or a hole shape in the insulating layer, it is recently required to form a through hole or a hole shape of a higher aspect ratio. For example, it is attempted to form a through hole or a hole shape having an aspect ratio higher than or equal to 20. However, if C₄F₆ gas as an additive gas for realizing a high selectivity is used to form a through hole or a hole shape of an aspect ratio higher than or equal to 20, etch stop readily occurs in a manner that the hole or opening is clogged and, thus, it is difficult to form a through hole or a hole shape of an aspect ratio higher than or equal to 20. Moreover, when a through hole or a hole shape of a high aspect ratio is formed, a so-called bowing shape in which a part of a through hole or a hole shape has a large diameter occurs readily. Therefore, it is also required to suppress generation of the bowing shape.

### SUMMARY OF THE INVENTION

In view of the above, the present invention provides a plasma etching method capable of forming a through hole or a hole shape of a high aspect ratio higher than or equal to 20 and obtaining a good etching shape while suppressing generation of a bowing shape, a plasma etching apparatus, a control program and a computer-readable storage medium.

In accordance with a first embodiment of the present invention, there is provided a plasma etching method for performing an etching process for forming on an insulating film formed on a substrate a hole shape having a ratio of depth to opening width of more than 20. The hole shape is formed on the insulating film by converting processing gas containing at least C₄F₆ gas and C₆F₆ gas into a plasma, wherein a flow rate ratio of the C₄F₆ gas to the C₆F₆ gas (C₄F₆ gas flow rate/C₆F₆ gas flow rate) ranges from about 2 to 11.

In accordance with a second embodiment of the present invention, there is provided a plasma etching method for performing an etching process for forming a through hole on an insulating film layer formed on a substrate with a width smaller than or equal to about 1/20 of a thickness of the insulating film layer by converting processing gas containing at least C₄F₆ gas and C₆F₆ gas into a plasma, wherein a flow rate ratio of the C₄F₆ gas to the C₆F₆ gas (C₄F₆ gas flow rate/C₆F₆ gas flow rate) ranges from about 2 to 11.

In accordance with a third embodiment of the present invention, there is provided a plasma etching method for etching a silicon oxide film formed on a substrate while using a carbon containing layer formed on the silicon oxide film as a mask, wherein the etching is performed by converting processing gas containing at least C₄F₆ gas and C₆F₆ gas into a plasma, wherein a flow rate ratio of the C₄F₆ gas to the C₆F₆ gas (C₄F₆ gas flow rate/C₆F₆ gas flow rate) ranges from about 2 to 11.

In the plasma etching method, the processing gas may contain rare gas and oxygen gas.

In the plasma etching method, an oxygen gas flow rate in the processing gas is preferably greater than or equal to a sum of a C₄F₆ gas flow rate and a C₆F₆ gas flow rate and smaller than or equal to 2.5 times the sum of the C₄F₆ gas flow rate and the C₆F₆ gas flow rate.

In the plasma etching method, the rare gas may be Ar gas.

In accordance with the present invention, there is provided a plasma etching apparatus including a processing chamber including therein a substrate; a processing gas supply unit for supplying processing gas into the processing chamber; a plasma generation unit for processing the substrate by converting the processing gas supplied from the processing gas supply unit into a plasma; and a control unit for controlling the above-described plasma etching method to be performed in the processing chamber.

In accordance with the present invention, there is provided a computer-executable control program for controlling, when executed, the plasma etching apparatus to perform the above-described plasma etching method.

In accordance with the present invention, there is provided a computer-readable storage medium storing therein a computer-executable control program, wherein, when executed, the control program controls a plasma etching apparatus to perform the plasma etching method described above.

In accordance with the present invention, it is possible to provide a plasma etching method capable of forming a through hole or a hole shape having a high aspect ratio higher than or equal to 20 and obtaining a good etching shape while suppressing generation of a bowing shape, a plasma etching apparatus, a control program and a computer-readable storage medium.

### BRIEF DESCRIPTION OF THE DRAWINGS

The objects and features of the present invention will become apparent from the following description of embodiments, given in conjunction with the accompanying drawings, in which:

FIGS. 1A and 1B show cross sectional configurations of a semiconductor wafer in accordance with an embodiment of a plasma etching method of the present invention;

FIG. 2 illustrates a schematic configuration of a plasma etching apparatus in accordance with an embodiment of the present invention; and

FIG. 3 provides a graph depicting etching results of a test example and a comparative example.

### DETAILED DESCRIPTION OF THE EMBODIMENT

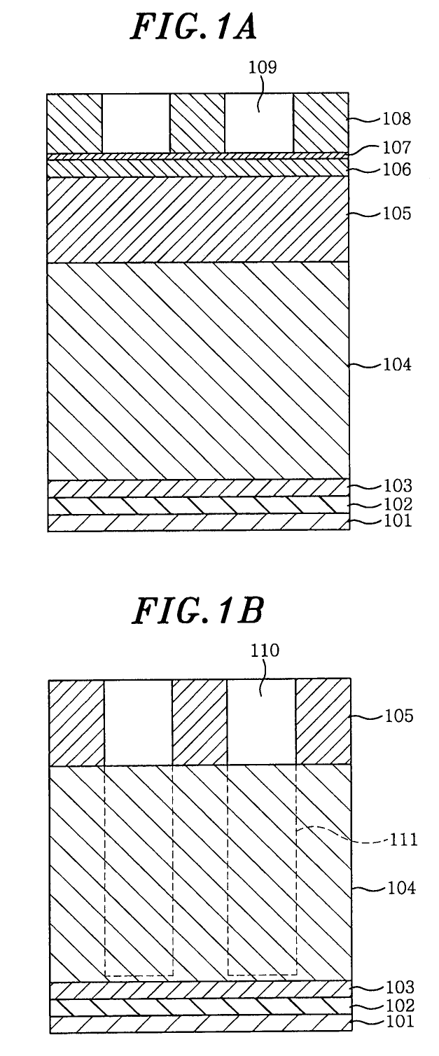

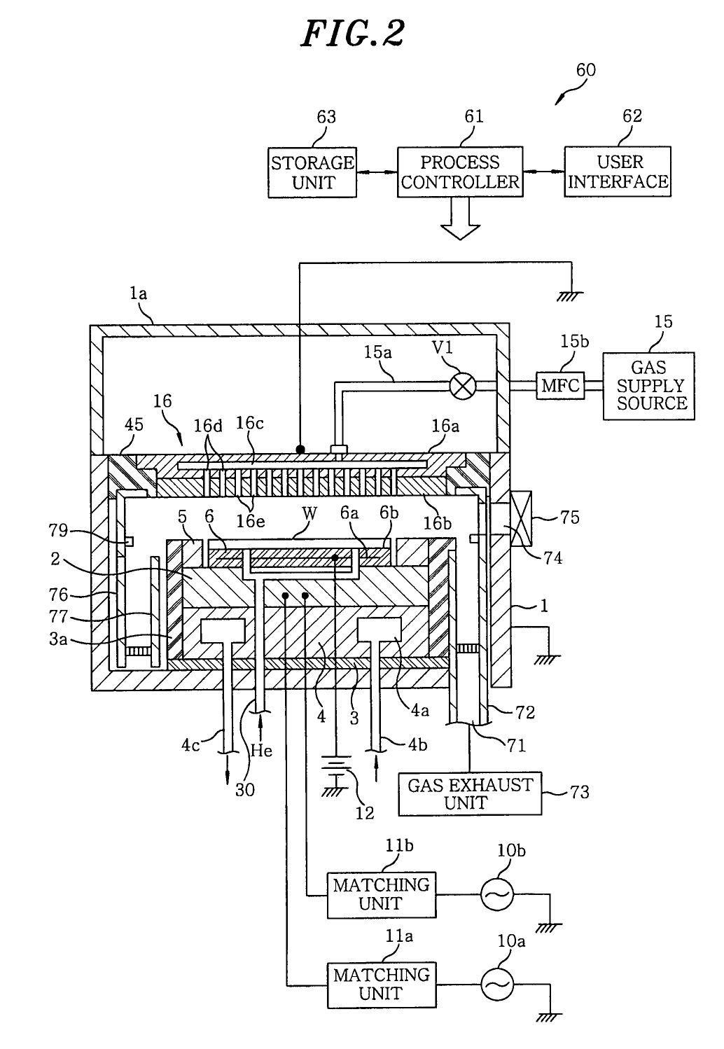

The embodiments of the present invention will be described with reference to the accompanying drawings which form a part hereof. FIGS. 1A and 1B show cross sectional configurations of a semiconductor wafer as a substrate to be processed in a plasma etching method in accordance with an embodiment of the present invention. Further, FIG. 2 illustrates a schematic configuration of a plasma etching apparatus in accordance with an embodiment of the present invention. First of all, the configuration of the plasma etching apparatus will be explained with respect to FIG. 2.

The plasma etching apparatus includes an airtight processing chamber 1 that is electrically grounded. This processing chamber 1 is formed in a cylindrical shape and is made of, e.g., aluminum or the like. Provided in the processing chamber 1 is a mounting table 2 for horizontally supporting a semiconductor wafer W as a substrate to be processed. The mounting table 2 is made of, e.g., aluminum, and is supported by a conductive supporting table 4 via an insulating plate 3. Further, a focus ring 5 formed of, e.g., single crystalline silicon, is provided at an upper periphery of the mounting table 2. Furthermore, a cylindrical inner wall member 3a made of, e.g., quartz or the like, is provided to surround the peripheral portions of the mounting table 2 and the supporting table 4.

The mounting table 2 is connected to a first RF power supply 10a via a first matching unit 11a, and is connected to a second RF power supply 10b via a second matching unit 11b. The first RF power supply 10a is used for plasma generate, and a high frequency power of a predetermined frequency (higher than or equal to about 27 MHz, e.g., about 40 MHz) is supplied from the first RF power supply 10a to the mounting table 2. Further, the second RF power supply 10b is used for ion attraction, and a high frequency power of a predetermined frequency (lower than or equal to about 13.56 MHz, e.g., about 3 MHz) lower than that from the first RF power supply 10a is supplied from the second RF power supply 10b to the mounting table 2. Meanwhile, a grounded shower head 16 is disposed above the mounting table 2 while facing the mounting table 2 in parallel. The mounting table 2 and the shower head 16 serve as a pair of electrodes.

Provided on the top surface of the mounting table 2 is an electrostatic chuck 6 for electrostatically adsorbing the semiconductor wafer W. The electrostatic chuck 6 is formed by embedding an electrode 6a in an insulator 6b, and the electrode 6a is connected to a DC power supply 12. Further, by applying a DC voltage from the DC power supply 12 to the electrode 6a, the semiconductor wafer W is adsorbed by a Coulomb force.

A coolant path 4a is formed inside the supporting table 4, and is connected to a coolant inlet line 4b and a coolant outlet line 4c. Further, by circulating an appropriate coolant, e.g., cooling water or the like, through the coolant path 4a, the supporting table 4 and the mounting table 2 can be controlled at a predetermined temperature. Moreover, a backside gas supply line 30 for supplying a cold heat transfer gas (backside gas) to the backside of the semiconductor wafer W is provided to pass through the mounting table 2 and the like. The backside gas supply line 30 is connected to a backside gas supply source (not shown). Due to the above configuration, the semiconductor wafer W electrically adsorbed on the top surface of the mounting table 2 by the electrostatic chuck 6 can be controlled to a predetermined temperature.

The shower head 16 is provided at a ceiling wall portion of the processing chamber 1. The shower head 16 has a main body 16a and an upper ceiling plate 16b forming an electrode plate, and is supported at an upper portion of the processing chamber 1 via a supporting member 45. The main body 16a is made of a conductive material, e.g., aluminum having an anodically oxidized surface, and the upper ceiling plat 16b is detachably supported on the bottom of the main body 16a.

A gas diffusion space 16c is provided inside the main body 16a, and a plurality of gas through holes 16d are formed at the bottom of the main body 16a to be positioned at the bottom of the gas diffusion space 16c. In addition, gas inlet holes 16e are provided at the upper ceiling plate 16b to pass through the upper ceiling plate 16b in a width direction while being overlapped with the gas through holes 16d. Due to this configuration, a processing gas supplied to the gas diffusion space 16c is supplied and diffused in the processing chamber 1 in a shower shape via the gas through holes 16d and the gas inlet holes 16e. Besides, the main body 16a and the like are provided with lines (not shown) for circulating a coolant, so that the shower head 16 can be cooled to a desired temperature during the plasma etching process.

Formed in the main body 16a is a gas inlet port 16d for introducing a processing gas into the gas diffusion space 16c. The gas inlet port 16d is connected to one end of a gas supply line 15a, and the other end of the gas supply line 15a is connected to a processing gas supply source 15 for supplying a processing gas for etching (etching gas). The gas supply line 15a is provided with a mass flow controller MFC 15b and an opening/closing valve V1 disposed thereon in that order from the upstream side. Further, the processing gas for plasma etching from the processing gas supply source 15, e.g., a gaseous mixture of Ar/O₂/C₄F₆/C₆F₆, is supplied to the gas diffusion space 16c via the gas supply line 15a, and then is supplied to the processing chamber 1 in a shower shape via the gas through holes 16d and the gas inlet openings 16e.

A cylindrical ground conductor la extends upward from the sidewall of the processing chamber 1 to be located at a position higher than the height position of the shower head 16. The cylindrical ground conductor 1a has a ceiling wall at the top thereof.

A gas exhaust port 71 is formed at the bottom of the processing chamber 1, and a gas exhaust unit 73 is connected to the gas exhaust port 71. By operating a vacuum pump provided in the gas exhaust unit 73, the inside of the processing chamber 1 can be depressurized to a predetermined vacuum level. Meanwhile, a loading/unloading port 74 for the wafer W is provided at a sidewall of the processing chamber 1, and a gate valve 75 for opening or closing the loading/unloading port 74 is provided at the loading/unloading port 74.

Reference numerals 76 and 77 in the drawing are deposition shields that are detachably installed. The deposition shield 76 is provided along the inner wall surface of the processing chamber 1, and prevents etching by-products (deposits) from being attached to the processing chamber 1. A conductive member (GND block) 79 DC-connected to the ground is provided to a portion of the deposition shield 76 at a height position substantially same as the height of the semiconductor wafer W. With this configuration, an abnormal discharge can be prevented.

The whole operation of the plasma etching apparatus configured as described above is controlled by a control unit 60. The control unit 60 has a process controller 61 which has a CPU and controls respective parts of the plasma etching apparatus, a user interface 62 and a storage unit 63.

The user interface 62 includes a keyboard for a process manager to input commands to operate the plasma etching apparatus, a display for visualizing an operational status of the plasma etching apparatus, and the like.

The storage unit 63 stores therein recipes including a control program (software), processing condition data and the like for realizing various processes performed by the plasma etching apparatus under the control of the process controller 61. Moreover, when a command is received from the user interface 62, a necessary recipe is retrieved from the storage unit 63 and executed by the process controller 61, so that a desired process is performed by the plasma etching apparatus under the control of the process controller 61. Further, the recipes including the control program, the processing condition data and the like can be stored in a computer-readable storage medium (for example, a hard disk, a CD, a flexible disk, a semiconductor memory, or the like) or can be used on-line by being transmitted, when needed, from another apparatus, via, e.g., a dedicated line.

Hereinafter, a process sequence of plasma-etching an silicon oxide film and the like formed on the semiconductor wafer W, which is performed by the plasma etching apparatus configured as described above, is explained. First, the gate valve 75 is opened, and the semiconductor wafer W is loaded from the loading/unloading port 74 into the processing chamber 1 by a transfer robot (not shown) or the like via a load lock chamber (not shown), and then is mounted on the mounting table 2. Thereafter, the transfer robot is retreated from the processing chamber 1, and the gate valve 75 is closed. Then, the processing chamber 1 is evacuated by the vacuum pump of the gas exhaust unit 73 via the gas exhaust port 71.

After the inside of the processing chamber 1 reaches a predetermined vacuum level, a predetermined processing gas (etching gas) is introduced from the gas supply source 15 into the processing chamber 1, and the inside of the processing chamber 1 is maintained at a certain pressure level, e.g., about 2.66 Pa (20 mTorr). In this state, a high frequency power of a frequency of, e.g., about 40 MHz, is supplied from the first RF power supply 10a to the mounting table 2. Further, a high frequency power of a frequency of, e.g., about 3 MHz, for ion attraction is supplied from the second RF power supply lob to the mounting table 2. At this time, a predetermined DC voltage is applied from the DC power supply 12 to the electrode 6a of the electrostatic chuck 6, and the semiconductor wafer W is electrostatically adsorbed by a Coulomb force.

In this case, due to the application of the high frequency powers to the mounting table 2 as described above, an electric field is formed between the shower head 16 serving as the upper electrode and the mounting table 2 serving as the lower electrode. A discharge is generated in a processing space in which the semiconductor wafer W is provided, and the silicon oxide film and the like formed on the semiconductor wafer W are etched by the plasma of the processing gas which is generated by the discharge.

Upon the completion of the etching process, the supply of the high frequency powers and the processing gas is stopped, and the semiconductor wafer W is unloaded from the processing chamber 1 in the reverse sequence as described above.

Hereinafter, a plasma etching method in accordance with an embodiment of the present invention will be described with reference to FIGS. 1A and 1B. FIGS. 1A and 1B are enlarged views of principal parts of a semiconductor wafer W as a substrate to be processed in the present embodiment. As shown in FIG. 1A, an oxide film layer 102 (thickness of, e.g., about 70 nm) and an SiN layer 103 (thickness of, e.g., about 50 nm) are formed on a silicon substrate 101, and an insulating film layer as an etching target layer, e.g., silicon oxide layer 104 (thickness of, e.g., about 3000 nm), is formed on the SiN layer 103.

Formed on the silicon oxide film 104 are a carbon-containing amorphous carbon layer (ACL) (thickness of, e.g., about 700 nm) 105, an SiON layer 106 (thickness of, e.g., about 80 nm) and an O-ARC film (organic-antireflection coating film) 107 (thickness of, e.g., about 38 nm). Formed on the O-ARC film 107 is a photoresist film 108 (thickness of, e.g., about 160 nm) patterned in a predetermined pattern. Openings 109 of the pattern formed in the photoresist film 108 are formed in a circular shape having a diameter of, e.g., about 80 nm.

The semiconductor wafer W having the above structure is accommodated in the processing chamber 1 in the apparatus in FIG. 2, and is mounted on the mounting table 2. Next, in a state shown in FIG. 1A, the O-ARC film 107, the SiON film 106, the amorphous carbon layer 105 are etched by using the photoresist layer 108 as a mask and the O-ARC film 107 and the SiON film 106 are removed. As a consequence, openings 110 are formed as shown in a state of FIG. 1B.

Thereafter, in a state shown in FIG. 1B, the silicon oxide layer 104 is plasma-etched by using the amorphous carbon layer 105 as a mask, thereby forming hole shapes 111, as indicated by a dotted line in FIG. 1B. In this case, when the opening diameter of each of the openings 109 formed in the photoresist layer 108 is about 80 nm, the thickness of the silicon oxide film 104 is about 3000 nm, as described above, and the hole shape 111 is formed up to the vicinity of the bottom portion of the silicon oxide film 104, the aspect ratio of about 40 is obtained.

In the plasma etching of the present embodiment, the processing gas containing at least C₄F₆ gas and C₆F₆ gas is used. A flow rate ratio of C₄F₆ gas to C₆F₆ gas (C₄F₆ gas flow rate/C₆F₆ gas flow rate) ranges from about 2 to about 11. Here, C₄F₆ gas and C₆F₆ are added to increase selectivity by generating deposits. For that reason, as for the processing gas, there is used a gaseous mixture of C₄F₆ gas, C₆F₆, O₂ gas and another gas for etching the silicon oxide layer 10, e.g., rare gas (e.g., Ar gas). In this case, however, the rare gas such as Ar gas or the like is used to facilitate ignition of a plasma and stabilize the plasma without causing a chemical reaction. As for the rare gas, there may also be used, e.g., Xe gas or the like.

In a test example 1, the plasma etching process was performed on the semiconductor wafer having the structure shown in FIG. 2 by using the plasma processing apparatus in FIG. 2 according to the following recipes.

The processing recipes of the test example 1 will be described bellow are retrieved from the storage unit 63 in the control unit 60, and are provided to the process controller 61. When the process controller 61 controls the respective parts of the plasma processing apparatus based on the control program, the plasma etching process is performed in accordance with the retrieved processing recipes.

Processing gas: Ar/O₂/C₄F₆/C₆F₆=200/65/55/5 sccm

Pressure: 2.66 Pa (20 mTorr)

Frequency of high frequency power: 40/3 MHz

In the test example 1, the semiconductor wafer W that has been subjected to the plasma etching was monitored by an electron microscope. As a result, it was found that when the etching rate of the silicon oxide layer/the etching rate of the amorphous carbon layer (hereinafter, referred to as selectivity) was about 61, the mask remaining amount was large; a good sidewall shape was obtained without a bowing shape; a hole shape having an aspect ratio larger than or equal to 20 (about 40) was etched.

Next, in a comparative example, the plasma etching process was performed under the following conditions same as those in the test example 1 except that the processing gas without C₆F₆ gas was used.

Processing gas: Ar/O₂/C₄F₆=200/65/60 sccm

Pressure: 2.66 Pa (20 mTorr)

Frequency of high frequency power: 40/3 MHz

As a result, the selectivity was about 19, and the mask remaining amount was greatly reduced compared to that in the test example 1.

Thereafter, in a test example 2, the plasma etching was performed under the following conditions same as those in the test example 1 except for changing the flow rate ratio of gases contained the processing gas used.

Processing gas: Ar/O₂/C₄F₆/C₆F₆=200/75/50/10 sccm

As a result, when the selectivity was larger than or equal to about 100, the mask remaining amount was large; a good sidewall shape was obtained without a bowing shape; and a hole shape having an aspect ratio larger than or equal to 20 (about 40) was etched.

Next, in a test example 3, the plasma etching was performed under the following conditions same as those in the test example 1 except for hanging the flow rate ratio of gases contained the of the processing gas used.

Processing gas: Ar/O₂/C₄F₆/C₆F₆=200/93/40/20 sccm

As a result, when the selectivity was larger than or equal to about 100, the mask remaining amount was large; a good sidewall shape was obtained without a bowing shape; and a hole shape having an aspect ratio larger than or equal to 20 (about 40) was etched.

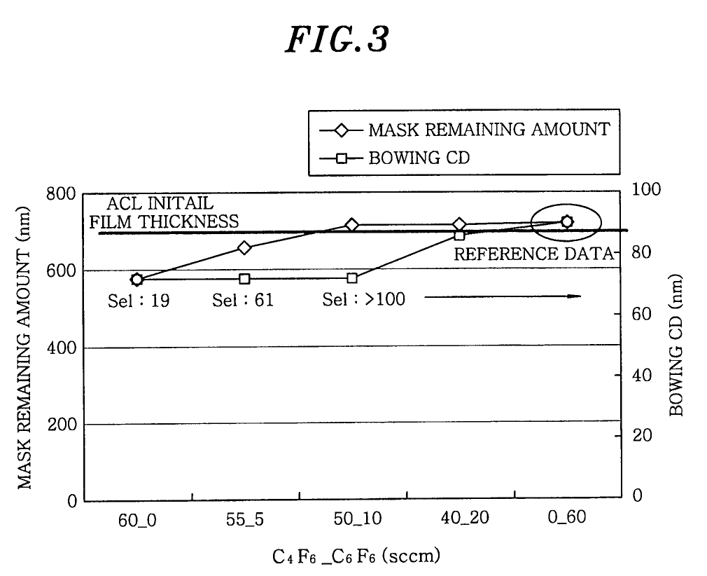

FIG. 3 provides a graph showing the results of the test examples 1 to 3 and the comparative example. In FIG. 3, a vertical axis represents a mask remaining amount (nm) and a bowing CD (critical dimension) (nm); a plot by a rhombus notation indicates the mask remaining amount; and a plot by a square notation presents the bowing CD. Moreover, an initial film thickness of the mask (ACL (amorphous carbon layer)) was about 700 nm. Further, the bowing CD (nm) in FIG. 3 indicates a CD measured in a portion having a maximum diameter of an etched hole shape. In this case, the initial CD of the opening of the photoresist mask is about 80 nm. Thus, the bowing shape is small when the measured value is close to about 80 nm.

In the graph shown in FIG. 3, starting from left, the first rhombus and square notations indicate the result of the comparative example (C₄F₆/C₆F₆=60/0 sccm); the second ones indicate the result of the test example (C₄F₆/C₆F₆=55/5 sccm); the third ones present the result of the test example 2 (C₄F₆/C₆F₆=50/10 sccm); and the fourth ones presents the result of the test example 3 (C₄F₆/C₆F₆=40/20 sccm).

Besides, the right most rhombus and square notations in the graph shown in FIG. 3 indicate reference data (C₄F₆/C₆F₆=0/60 sccm). In the reference data, the mask remaining amount increases over the initial film thickness (i.e., etch stop), and the bowing CD also increases.

As described above, in the test examples 1 to 3 in which the flow rate ratio of C₄F₆ gas to C₆F₆ gas (C₄F₆ gas flow rate/C₆F₆ gas flow rate) ranges from about 2 to about 11, the selectivity was greatly improved compared to that in the comparative example; generation of the bowing shape was suppressed; and the etching was performed in a good sidewall shape. Although the case of forming the hole shape was described in the test examples 1 to 3, the present invention may be applied to the case of forming a through hole.

The O₂ gas flow rate in the test examples 1 to 3 was increased compared to that in the comparative example, in order to prevent the etch stop by the addition of C₆F₆ gas as a deposition gas. The O₂ gas flow rate is preferably greater than or equal to the sum of the C₄F₆ gas flow rate and the C₆F₆ gas flow rate, and is smaller than or equal to 2.5 times the sum of the C₄F₆ gas flow rate and C₆F₆ gas flow rate.

This is because the C₄F₆ gas flow rate needs to be substantially the same as the O₂ gas flow rate and the C₆F₆ gas flow rate needs to be greater than the O₂ gas flow rate by about 2.5 times. This relationship is indicated as follows:

O₂gas flow rate=(C₄F₆ gas flow rate)+2.5×(C₆F₆ gas flow rate).

As set forth above, in accordance with the present embodiment, it is possible to form a through hole or a hole shape having an aspect ratio higher than or equal to 20, and also possible to obtain a good etching shape while suppressing generation of a bowing shape. Further, the present invention is not limited to the above-described embodiment but can be modified in various ways. For example, the plasma etching apparatus is not limited to the parallel plate type apparatus which applies dual frequency powers to the lower electrode, but it can be of a type which applies respective high frequency powers to the upper and lower electrodes, or a type which applies single frequency power to the lower electrode, and the like.

While the invention has been shown and described with respect to the embodiments, it will be understood by those skilled in the art that various changes and modification may be made without departing from the scope of the invention as defined in the following claims.

What is claimed is:

1. A plasma etching method for performing an etching process for forming on an insulating film formed on a substrate a hole shape having a ratio of depth to opening width of more than 20, wherein the hole shape is formed on the insulating film by converting processing gas containing at least C₄F₆ gas and C₆F₆ gas into a plasma, wherein a flow rate ratio of the C₄F₆ gas to the C₆F₆ gas (C₄F₆ gas flow rate/C₆F₆ gas flow rate) ranges from about 2 to 11.

2. A plasma etching method for performing an etching process for forming a through hole on an insulating film layer formed on a substrate with a width smaller than or equal to about 1/20 of a thickness of the insulating film layer by converting processing gas containing at least C₄F₆ gas and C₆F₆ gas into a plasma, wherein a flow rate ratio of the C₄F₆ gas to the C₆F₆ gas (C₄F₆ gas flow rate/C₆F₆ gas flow rate) ranges from about 2 to 11.

3. A plasma etching method for etching a silicon oxide film formed on a substrate while using a carbon containing layer formed on the silicon oxide film as a mask, wherein the etching is performed by converting processing gas containing at least C₄F₆ gas and C₆F₆ gas into a plasma, wherein a flow rate ratio of the C₄F₆ gas to the C₆F₆ gas (C₄F₆ gas flow rate/C₆F₆ gas flow rate) ranges from about 2 to 11.

4. The plasma etching method of claim 1, wherein the processing gas contains rare gas and oxygen gas.

5. The plasma etching method of claim 4, wherein an oxygen gas flow rate in the processing gas is greater than or equal to a sum of a C₄F₆ gas flow rate and a C₆F₆ gas flow rate and smaller than or equal to 2.5 times the sum of the C₄F₆ gas flow rate and the C₆F₆ gas flow rate.

6. The plasma etching method of claim 4, wherein the rare gas is Ar gas.

7. A plasma etching apparatus comprising:
a processing chamber including therein a substrate;
a processing gas supply unit for supplying processing gas into the processing chamber;
a plasma generation unit for processing the substrate by converting the processing gas supplied from the processing gas supply unit into a plasma; and
a control unit for controlling the plasma etching method described in claim 1 to be performed in the processing chamber.

8. A plasma etching apparatus comprising:
a processing chamber including therein a substrate;
a processing gas supply unit for supplying processing gas into the processing chamber;
a plasma generation unit for processing the substrate by converting the processing gas supplied from the processing gas supply unit into a plasma; and
a control unit for controlling the plasma etching method described in claim 2 to be performed in the processing chamber.

9. A plasma etching apparatus comprising:
a processing chamber including therein a substrate;
a processing gas supply unit for supplying processing gas into the processing chamber;
a plasma generation unit for processing the substrate by converting the processing gas supplied from the processing gas supply unit into a plasma; and
a control unit for controlling the plasma etching method described in claim 3 to be performed in the processing chamber.

10. A computer-readable storage medium storing therein a computer-executable control program, wherein, when executed, the control program controls a plasma etching apparatus to perform the plasma etching method described in claim 1.

11. A computer-readable storage medium storing therein a computer-executable control program, wherein, when executed, the control program controls a plasma etching apparatus to perform the plasma etching method described in claim 2.

12. A computer-readable storage medium storing therein a computer-executable control program, wherein, when executed, the control program controls a plasma etching apparatus to perform the plasma etching method described in claim 3.
